(19) United States
(12) Patent Application Publication
(10) Pub. No.: US 2018/0337081 A1
(43) Pub. Date: Nov. 22, 2018

(54) ELECTRICAL FEEDS WITH LOW LOSS COATING MATERIALS FOR HIGH TEMPERATURE ELECTROSTATIC CHUCKS

(71) Applicant: Applied Materials, Inc., Santa Clara, CA (US)

(72) Inventor: Zheng John YE, Santa Clara, CA (US)

(21) Appl. No.: 15/965,658

(22) Filed: Apr. 27, 2018

Related U.S. Application Data
(60) Provisional application No. 62/507,511, filed on May 17, 2017.

(51) Int. Cl. H01L 21/683; H01L 21/67; C25D 3/48; C25D 3/46; C25D 7/00; H05B 3/08; H05B 3/18; H05B 3/28; H05B 3/12

(52) U.S. Cl. CPC H01L 21/6833; H01L 21/67103; C25D 3/48; C25D 3/46; C25D 7/00; H05B 2203/017; H05B 3/18; H05B 3/283; H05B 3/12; H05B 2203/016; H05B 3/08

(57) ABSTRACT

Implementations of the present disclosure include methods and apparatuses utilized to maintain or increase the electrical conductivity of an electrical feed through in a high temperature electrostatic chuck (ESC) within a processing chamber. In one implementation, the ESC has a dielectric body. The dielectric body has a chucking mesh and a metal mesh. A RF rod is formed from a first material, has an outer surface, and is attached to the chucking mesh. A conductive protective coating disposed on the outer surface of the RF rod.

### CROSS-REFERENCE TO RELATED APPLICATIONS

This application claims benefit of U.S. Provisional Application Ser. No. 62/507,511, filed May 17, 2017 (Attorney Docket No. APPM/024808USL2), which is incorporated by reference in its entirety.

### BACKGROUND

### Field

Implementations of the present disclosure generally relate to semiconductor processing systems. More specifically, implementations of the disclosure relates to electrical feeds in a high temperature electrostatic chuck for use in semiconductor processing systems.

### Description of the Related Art

Reliably producing nanometer and smaller features is one of the key technology challenges for next generation very large scale integration (VLSI) and ultra large-scale integration (ULSI) of semiconductor devices. However, as the limits of circuit technology are pushed, the shrinking dimensions of VLSI and ULSI interconnect technology have placed additional demands on processing capabilities. Reliable formation of gate structures on the substrate contributes to VLSI and ULSI success and to the continued effort to increase circuit density and quality of individual substrates and die.

To drive down manufacturing cost, integrated chip (IC) manufactures demand higher throughput and better device yield and performance from every silicon substrate processed. Some fabrication techniques being explored for next generation devices under current development require processing at temperatures exceeding 300 degrees Celsius and utilizing high biasing power to produce high quality films in the manufacture of these devices. A substrate support assembly may hold, or chuck, the substrate on an electrostatic chuck for processing at these high temperatures. However, at temperatures approaching 150 degrees Celsius or above, power usage for conventional electrostatic chucks (ESC) that provide both biasing and heating increases over time due to oxidation internal components such as the power terminal leads disposed in the ESC. The oxidation causes the power terminal leads to become more resistive and thus, less conductive. The increase in power may cause overheating of the internal components in the ESC and damage thereto. Additionally, the increased power usage increases the manufacturing operation costs. The damage due to the elevated temperatures and power eventually results in the premature replacement of the ESC.

Thus, there is a need for an improved substrate support assembly having an electrostatic chuck suitable for use at processing temperatures above 300 degrees Celsius.

### SUMMARY

Implementations of the present disclosure include methods and apparatuses utilized to maintain or increase the electrical conductivity of an electrical feed through in a high temperature electrostatic chuck (ESC), heater, within a processing chamber. In one implementation, the heater has a dielectric body. The dielectric body has a chucking mesh and a metal mesh. A RF rod is formed from a first material, has an outer surface, and is attached to the chucking mesh. A conductive protective coating is disposed on the outer surface of the RF rod, wherein the conductive protective coating is formed from one of gold, silver or copper.

In a second implementation, a heater has a dielectric body. The dielectric body has a chucking mesh and a metal mesh. A metal mesh transmission line is formed from a first material, has an outer surface, and is attached to the metal mesh. A conductive protective coating disposed on the outer surface of the metal mesh transmission line, wherein the conductive protective coating is formed from one of gold, silver or copper.

In a third implementation, a method for forming a protective coating on a rod brazed to a mesh in a ceramic heater is disclosed. The method begins by attaching the rod to the mesh, the rod having an outer surface. The method includes bonding a protective coating to the outer surface of the rod.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings.

FIG. 1 depicts a side schematic view of a processing chamber having an electrostatic chuck (ESC) according to one implementation of the present disclosure.

FIG. 2 is a cross-sectional schematic of one embodiment of the ESC having multi-zone heaters and a bottom mesh RF path.

FIG. 3 depicts a partial cross-sectional schematic view for one transmission rod in the ESC of FIG. 2 taken along line 3-3.

It is to be noted, however, that the appended drawings illustrate only typical implementations of this disclosure and are therefore not to be considered limiting of its scope, for the disclosure may admit to other equally effective implementations.

To facilitate understanding, identical reference numerals have been used, where possible, to designate identical elements that are common to the figures.

### DETAILED DESCRIPTION

An improved substrate support assembly having a ceramic heater, or high temperature electrostatic chuck (HT ESC), for processing a substrate at high temperatures is disclosed herein. A method and apparatus to plate low melting point, high conductivity, low permeability materials over high melting point, low conductivity, and high permeability materials on the ceramic heaters used in Chemical Vapor Deposition (CVD) and other plasma processing systems is also disclosed herein. The ceramic heater has a nickel feedthrough rod that conventionally would develop oxide when operating at temperatures between about 300° C. and about 700° C. temperature. It is recognized that the RF impedance increases for the oxidized feedthrough rods leading to loss in power. Here, a silver over-layer prevents the loss of power as the over-layer oxides have a relatively high conductivity as compared to the conventional feedthrough rod. Alternately, gold, which does not oxidize at the operating temperatures, may be used as the over-layer.

It is recognized in the current disclosure that plating under low temperature environment of less than 200° C. on the feedthrough rods after dip-brazing the feedthrough rods having a high melting point, will prevent the over-layer from nearing the melting point of the over-layer and therefore preserving the over-layer. Methods for creating the over-layer coating, such as with a brush-painting method, are also disclosed.

The feed through rods include high melting point, low conductivity, and high permeability materials such as nickel, titanium, molybdenum, etc., and an over-layer of low melting point, high conductivity, low permeability materials to carry most of the current therethrough. A range of materials for the over-layer for the feedthrough rods are contemplated, including gold, silver, etc. A method of dip-brazing the high melting point, low conductivity, and high permeability materials to make the connections to the embedded heating elements and RF electrodes under temperatures of about 1000° C. or less, are disclosed. The method includes plating the high melting point, low conductivity, and high permeability materials, such as gold and silver, under temperatures of about 200° C. or less, and further includes associated methods of annealing and treating the over-layer to improve coating uniformity and to reduce mechanical stress for the over-layer.

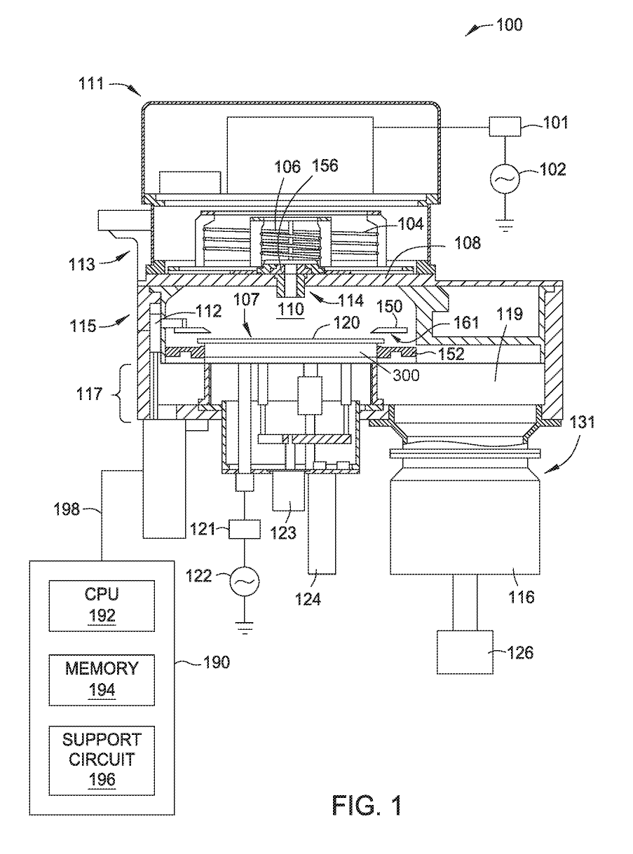

FIG. 1 depicts a side schematic view of a processing chamber 100 according to one implementation of the present disclosure. The processing chamber 100 may be a plasma process chamber, such as an inductively coupled plasma (ICP) processing chamber, a Decoupled Plasma Nitridation high dose (DPN HD) processing chamber, or other processing chamber. The processing chamber 100 may be a fully automated semiconductor plasma processing chamber of the kind which is employed as part of a multi-chamber modular system (not shown). As shown in FIG. 1, the processing chamber 100 includes a body 115, a lid 108, and a substrate support assembly 107 disposed within the body 115. A substrate entry port 112 is formed in the body 115 to facilitate entry and removal of the substrate 120 from the processing chamber 100. The body 115, the lid 108 and the substrate support assembly 107 substantially define a processing volume 110. The processing volume 110 may be configured to accommodate a substrate 120 having a nominal diameter size up to 12 inch (300 mm), 18 inch (450 mm), or other diameter.

The processing chamber 100 includes a plasma power source 102 and a matching network 101. The plasma power source 102 and the matching network 101 are in communication with a power generating apparatus. The power generating apparatus is housed within a first enclosure 111 disposed on the body 115 and controls the operation of power from the plasma power source 102 into the processing chamber 100. The plasma power source 102 and matching network 101 operate at a frequency which is typically in the range of about 12 MHz to about 13.5 MHz. If desired, the plasma power source 102 may be operated at a frequency up to 60 MHz. In various implementations, the plasma power source 102 may be operated at a power in the range from about 0.1 kW to about 5 kW. Inductive coils 104, 106 may be located within a second enclosure 113 disposed between the body 115 and the first enclosure 111. When energized by the plasma power source 102, the inductive coils 104, 106 generate an RF field in the processing volume 110 that can form a plasma from a gas in the processing volume 110. The plasma can then be used to perform a plasma process on the substrate 120.

The lid 108 includes a cover member, which may be a plate, having a central opening adapted to receive a gas coupling insert 114. The gas coupling insert 114 may include a cylindrical hollow body having a plurality of axial through holes formed in the bottom of the cylindrical hollow body. A gas connector 156 may be disposed on the lid 108. A processing gas (not shown) is introduced into the gas connector 156 to through holes of the gas coupling insert 114, which provide uniform controlled gas flow distribution in the processing volume 110.

The processing volume 110 present within the body 115 is in fluid communication with a non-processing volume 117. The non-processing volume 117 is in fluid communication with a throttle valve 119. The throttle valve 119 communicates with an exhaust system 131 that may include a turbo pump 116 and a roughing pump 126, all in fluid communication with the throttle valve 119. Exhaust gases may flow from the throttle valve 119 sequentially through the turbo pump 116 and the roughing pump 126. In operation, plasma source gas is provided to the processing volume 110 and processing by-products are exhausted from the processing volume 110 through the throttle valve 119 and the exhaust system 131.

The processing chamber 100 has a controller 190. The controller 190 may include a central processing unit (CPU) 192, a memory 194, and a support circuit 196 utilized to control the process sequence and regulate the gas flows and plasma process performed in the processing chamber 100. The CPU 192 may be of any form of a general purpose computer processor that may be used in an industrial setting. The software routines such as the etching process described below can be stored in the memory 194, such as random access memory, read only memory, floppy, or hard disk drive, or other form of digital storage. The support circuit 196 is conventionally coupled to the CPU 192 and may include cache, clock circuits, input/output systems, power supplies, and the like. Bi-directional communications between the controller 190 and the various components of the processing chamber 100 are handled through numerous signal cables collectively referred to as signal buses 198, some of which are illustrated in FIG. 1. The controller 190 may control the operations of the plasma power source 102 and matching network 101, the processing gas, the roughing pump 126, the RF bias power, and other chamber operations and components such as the substrate support assembly 107.

The substrate support assembly 107 has a high temperature electrostatic chuck (HT ESC) 300. The HT ESC 300 is disposed within the processing volume 110 of the body 115 and is configured to support the substrate 120 during processing. The substrate support assembly 107 may have a lift pin assembly 123. The lift pin assembly 123 is operable to move lift pins generally in a vertical direction. Substrates disposed on the HT ESC 300 may be raised and lowered by means of the lift pins to facilitate transfer of the substrate 120 onto and off of the HT ESC 300.

A shadow ring 150 may be disposed adjacent to an edge ring 152 circumscribing a periphery region of the HT ESC 300. The edge ring 152 is shaped in a manner to define a cavity 161 between the edge ring 152 and the shadow ring 150. The cavity 161 defines a constrained flow path that allows plasma to flow in a direction away from a substrate bevel and be pumped out of the processing chamber through the cavity 161 to the roughing pump 126, rather than accumulating and forming a residual film layer on the substrate bevel or backside.

A fluid conduit 124 is coupled to the substrate support assembly 107 to maintain the temperature thereof in a desired range. The HT ESC 300 may be operable at temperatures exceeding about 300 degrees Celsius. For example, the temperature set point for the HT ESC 300 may be held at 450 degrees Celsius or higher.

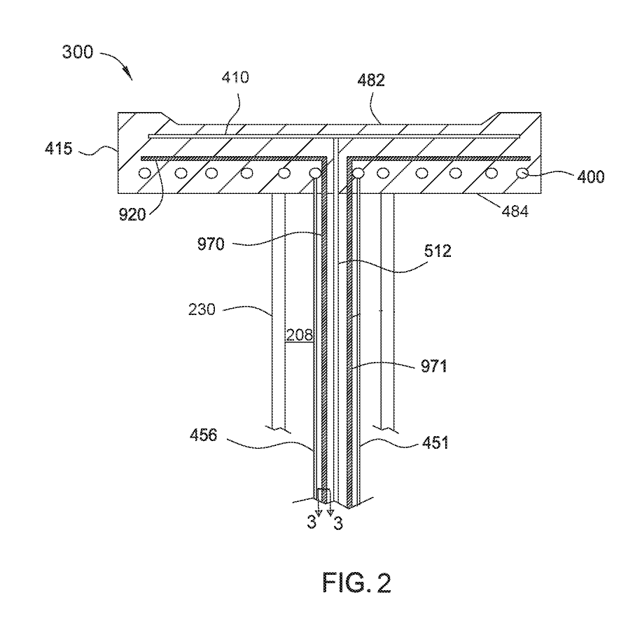

During processing of substrates 120 in the processing chamber 100, the HT ESC 300 experiences temperatures in excess of 300 degrees Celsius, such as 450 degrees Celsius. The HT ESC 300 disclosed herein is configured to chuck the substrate 120 during the high temperature processing. The HT ESC 300 will be described briefly with reference to FIG. 2 which is a cross-sectional schematic of one embodiment of the HT ESC 300 having multi-zone heaters and a bottom mesh RF path.

The HT ESC 300 has a dielectric body 415. The dielectric body 415 may be formed from a ceramic material, such as AlN or other suitable ceramic. The dielectric body 415 has a top surface 482 configured to support a substrate thereon. The dielectric body 415 has a bottom surface 484 opposite the top surface 482. The substrate support assembly 107 includes a stem 230 attached to the bottom surface 484 of the dielectric body 415. The stem 230 couples the HT ESC 300 to the processing chamber 100. The stem 230 is configured as a tubular member, such as a hollow dielectric shaft, having an interior portion 208. The interior portion 208 has an environment at atmospheric pressure and is not in fluid communication with either the processing volume 110 or the non-processing volume 117 present within the body 115. Thus, the interior portion 208 is exposed to atmospheric gases such as oxygen and nitrogen.

The HT ESC 300 is configured as a multi-zone heater 400, having a central heater, an intermediary heater, and one or more outer heaters. Each multi-zone heater 400 is aligned with and defines a heating zone along the top surface 482 upon which a substrate is disposed during processing. A plurality of heater power supply lines 456 and heater power return lines 451 are attached to the multi-zone heater 400. The heater power lines 451, 456 provide power from the power source 464 for heating the HT ESC 300 in one or more of the zones. The multi-zone heater 400 is configured to heat the top surface 482 to temperatures which may exceed about 300 degrees Celsius, such as about 600 degrees Celsius. The heater power lines 451, 456 may be configured as solid rods such as nickel or other suitable material.

At least a portion of the HT ESC 300 is electrically conductive and biases a substrate 120 thereto for holding (i.e., chucking) the substrate 120 during processing. The substrate 120 may be biased by providing RF power from a RF bias power source 122 through a matching network 121. The matching network 121 is coupled to a chucking mesh in the HT ESC 300 through an RF rod 512 coupled to the chucking mesh 410. The RF rod 512 may be formed from nickel, molybdenum, titanium or other suitably conductive material. RF power provided by the RF bias power source 122 may be within the range of about 100 KHz to about 2 GHz, such as within the range of 350 KHz to 50 MHz. The plasma power source 102 and the RF bias power source 122 for biasing the substrate 120 are independently controlled by the controller 190.

HT ESC 300 has a second layer of metal mesh 920. The metal mesh 920 may be disposed between the multi-zone heater 400 and the chucking mesh 410 in the dielectric body 415 of the HT ESC 300. The metal mesh 920 has transmission rods 970, 971. The transmission rods 970, 971 are connected to the metal mesh 920 and traverse through the interior portion 208 of the stem 230. The transmission rods 970, 971 may be a solid rod and dip brazed, welded or joined by other suitable techniques to the metal mesh 920. In one embodiment, the transmission rods 970, 971 are dip-braised to the embedded metal mesh 920 at temperatures of above about 1000 degrees Celsius in a vacuum oven. Above the metal mesh 920, the chucking mesh 410, a first layer of metal mesh, functions to bias plasma ions to the substrate disposed on the HT ESC 300. During high temperature and high power operations, the transmission rods 970, 971 may achieve temperatures exceeding about 300 degrees Celsius, such as about 600 degrees Celsius or higher, such as about 900 degrees Celsius.

The transmission rods 970, 971 are substantially similar to the RF rod 512 and may be formed from solid rods of nickel, molybdenum, titanium, or other conductive material suitable for environmental temperatures exceeding 300 degrees Celsius. The transmission rods 970, 971 and the RF rod 512 will be discussed further in reference to transmission rod 970 only. It should be appreciated that the following discussion equally applies to many of the electrical feedthroughs in the HT ESC passing through the stem 230, including the transmission rod 971 and the RF rod 512.

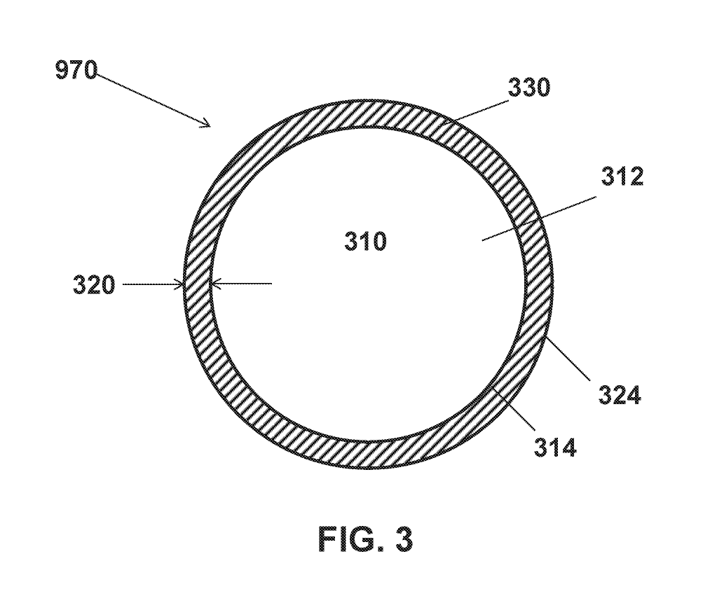

FIG. 3 depicts a partial cross-sectional schematic view for the transmission rod 970 in the HT ESC 300 taken along line 3-3. It should be appreciated that the protective coating applied to the transmission rod 970 and discussed with respect to FIG. 3 is equally applicable to an application on the RF rod 512. The transmission rod 970 has a core 310. The core 310 is surrounded by an outer protective coating 330. The core 310 is formed from a metal or their alloys for example copper, nickel, stainless steel, titanium, molybdenum, etc. and alloys containing other metals. The core 310 may have a diameter between about 3 mm and about 30 mm. The core 310 has an outer perimeter 314.

The protective coating 330 is applied/bonded to the outer perimeter 314 of the core 310. The application of the protective coating 330 may be performed after the transmission rod 970 is attached to the metal mesh 920. The protective coating 330 may be bonded in any suitable manner such as electro plating which will not degrade or otherwise compromise the bond between the metal mesh 920 and the transmission rod 970. For example, the protective coating 330 may utilize electrolytic plating to bond the coating to the metal part by the use of electrically-charged coatings. The charged coatings are chemically bonded to the core 310. Other example techniques may include barrel plating, rack plating, vibratory plating, etc. The protective coating 330 may have a thickness 320 of between 3 microns to about 5 microns. The thickness 320 may have a tolerance of less than of about 0.5 microns. It is further the intention of the current disclosure to use other methods to create the protective coating 330 which includes brush-painting and associated annealing and treating process to prevent coating appealing.

The protective coating 330 has an outer surface 324. The outer surface 324 is exposed to the environment inside the interior portion 208 of the stem 230. The protective coating 330 provides a barrier against chemical attacks, such as oxidation, to the transmission rod 970 in the HT ESC 300. The protective coating 330 may be formed from silver, gold, copper or other suitable material. In one example, gold is utilized as the protective coating 330 since gold will not form surface oxides. Gold conducts low voltage currents for long periods of time without corrosion or failure. Gold provides good wear resistance, especially when combined with cobalt or nickel. Silver will form surface oxides, however the silver oxides decompose under certain conditions at temperatures above 280° C. Moreover, it should be appreciated that the conductivity of silver oxide is not that much different than pure silver. Table 1 below provides some of the electrical properties of silver, gold and copper.

TABLE 1

| | Electrical conductivity | Electrical resistivity |
|---|---|---|
| Material | (10.E6 Siemens/m) | (10.E−8 Ohm · m) |
| Silver | 62.1 | 1.6 |
| copper | 58.5 | 1.7 |
| Gold | 44.2 | 2.3 |

The methods and apparatus described above are for electrical feedthroughs that connect to respective heaters and RF electrodes. The electrical feedthroughs have the protective coating 330 which is formed of low loss materials. Electrical feedthroughs having protective coating 330 may be used in Chemical Vapor Deposition equipment having operating temperatures of about 100 degrees Celsius to about 900 degrees Celsius, controlled RF voltage of about 5000 Vpp, RF current of about 100 App, DC voltage of up to about 2000 V, and DC current of up to about 10 A. The RF frequencies are in the range of 350 kHz up to 2 GHz including industrial frequency bands near 13.56 MHz, 27.12 MHz, 40 MHz, etc. as defined by FCC.

In particular to the disclosed implementation and range of operating parameters pertinent to CVD processes, multiple embedded heating elements and RF electrodes are connected to the feedthrough rods having the protective coating 330 on which the DC, AC, and RF currents are passed to control the substrate temperature, RF power, and DC voltage used to chuck the substrate to the surface of the HT ESC.

The feedthrough rods, during operation, are typically exposed to air environment having a temperature of about 100 degrees Celsius to about 750 degrees Celsius where an oxide layer may develop over time on the surface of the feedthroughs rods. The feedthroughs rods experience power loss as a result of the presence of the non-conductive oxide layers, leading to overheating, due to increased resistance, as well as further power loss. The loss mechanism is that of Ohmic loss at DC, AC and RF frequencies. In particular to the RF frequencies, the loss is associated with the surface layer of the oxidation skin depth of the surface into the metal body which carries most of the current.

As the skin depth reduces as frequency increases, more current will be flowing on the surface layer to the effect that the feedthrough becomes smaller in cross-section, leading to higher loss. Other metal properties affecting skin depth are conductivity and magnetic permeability, whereby the best class of metals for feedthroughs is those with high conductivity and low permeability. Example high conductivity and low permeability metals include gold, silver, copper, nickel, etc., among which copper and silver develop oxide in air at about 400 degree Celsius to 700 degree Celsius, while gold does not. Among developed metal oxides, silver oxides exhibit high conductivity, and copper and nickel have low conductivity. Thus, it is desirable from a loss point of view to use gold or silver as feedthroughs. However, these materials may not survive the dip-braising process in temperature environments over 1000 degrees Celsius. Thus, the protective coating 330 is applied to the core 310, i.e., feedthrough rod base material, after the dip-braze process.

In particular to the manufacturing process of coating gold or silver after the base contact rods are dip-brazed to the heating elements or the embedded RF electrodes, it is recognized that for example, electrolytic plating can be used. Electrolytic plating achieves several micro-meters of high conductivity surface materials at temperature well below the dip-braising temperatures so that the protective coating 330 does not reach the melting point. One example is a gold protective coating 330 on the nickel core 310, and as the result of the coating process, most of the current will flow through the protective coating 330 formed from the gold layer where the loss will be low as compared to nickel alone or a nickel oxide layer, NiO. A silver over layer will prevent the loss as silver oxide has comparable high conductivity as compared to metallic silver. A gold over layer also prevents loss as gold does not oxidize at operating temperatures disclosed herein.

Advantageously, the disclosed electrical feed through can be run with a lower resistance and a lower temperature, due to increased electrical conductivity at the disclosed operating temperatures. This in turn leads to significant power savings which translate to cost savings on utilities for running the equipment. Additionally, more power may be applied at the RF mesh without having to increase the power thereto due to loss in the electrical feed through. This increased efficiency prevents damage to the electrical feed through and extends the service life for the HT ESC.

While the foregoing is directed to implementations of the present disclosure, other and further implementations of the disclosure may be devised without departing from the basic scope thereof, and the scope thereof is determined by the claims that follow:

What is claimed is:

1. A heater having an electrical feed through for high temperature operations, comprising:
a dielectric body having a chucking mesh and a metal mesh;
a RF rod formed from a first material and having an outer surface, the rod attached to the chucking mesh; and
a conductive protective coating disposed on the outer surface of the RF rod, wherein the conductive protective coating is formed from one of gold, silver or copper.

2. The heater of claim 1, wherein the conductive protective coating is bonded to the outer surface by electroplating, barrel plating, rack plating, vibratory plating or brush-painting.

3. The heater of claim 1, wherein the conductive protective coating is formed from silver.

4. The heater of claim 3, the conductive protective coating is formed from a gold material.

5. The heater of claim 3, wherein the conductive protective coating has a thickness of between about 3 microns to about 5 microns.

6. The heater of claim 1, wherein the electrical conductivity of an oxide of the RF rod is less than the electrical conductivity of an oxide of the conductive protective coating.

7. The heater of claim 1, wherein the RF rod is formed from a solid material comprising nickel, molybdenum, or titanium.

8. A heater having an electrical feed through for high temperature operations, comprising:
a dielectric body having a chucking mesh and a metal mesh;
a metal mesh transmission line formed from a first material and having an outer surface, the rod attached to the chucking mesh; and
a conductive protective coating disposed on the outer surface of the metal mesh transmission line, wherein the conductive protective coating is formed from one of gold, silver or copper.

9. The heater of claim 8, wherein the conductive protective coating is bonded to the outer surface by electroplating, barrel plating, rack plating, vibratory plating or brush-painting.

10. The heater of claim 9, wherein the conductive protective coating is formed from silver.

11. The heater of claim 9, the conductive protective coating is formed from a gold material.

12. The heater of claim 9, wherein the conductive protective coating has a thickness of between about 3 microns to about 5 microns.

13. The heater of claim 8, wherein the electrical conductivity of an oxide of the RF rod is less than the electrical conductivity of an oxide of the conductive protective coating.

14. The heater of claim 8, wherein the metal mesh transmission line is formed from a solid material comprising nickel, molybdenum, or titanium.

15. A method for forming a protective coating on a rod brazed to a mesh in a ceramic heater, the method comprising:
attaching the rod to the mesh, the rod having an outer surface;
bonding a protective coating to the outer surface of the rod.

16. The method of claim 15, wherein bonding comprises:
electrolytic plating a gold material as the protective coating to the rod by the use of electrically-charged coatings.

17. The method of claim 15, wherein bonding comprises one or more of barrel plating, rack plating, vibratory plating or brush-painting.

18. The method of claim 15, wherein the coating is one of gold, silver or copper.

19. The method of claim 18, wherein the coating has a thickness of between about 3 microns to about 5 microns.

20. The method of claim 18, wherein the protective coating is bonded to the outer surface by electroplating, barrel plating, rack plating, vibratory plating or brush-painting.
